(19) United States
(12) Patent Application Publication
(10) Pub. No.: US 2015/0259799 A1
(43) Pub. Date: Sep. 17, 2015

(54) VERTICAL HEAT TREATMENT APPARATUS, METHOD OF OPERATING VERTICAL HEAT TREATMENT APPARATUS, AND STORAGE MEDIUM

(71) Applicant: TOKYO ELECTRON LIMITED, Tokyo (JP)

(72) Inventors: Yutaka MOTOYAMA, Oshu-shi (JP); Kohei FUKUSHIMA, Oshu-shi (JP); Masanobu MATSUNAGA, Nirasaki City (JP); Pao-Hwa CHOU, Niraski City (JP)

(21) Appl. No.: 14/642,230

(22) Filed: Mar. 9, 2015

(30) Foreign Application Priority Data
Mar. 11, 2014 (JP) 2014-047790

(51) Int. Cl. C23C 16/46; C23C 16/458; H01L 21/02; C23C 16/455

(52) U.S. Cl. CPC C23C 16/46; C23C 16/455; C23C 16/458; H01L 21/0228; H01L 21/02299

(57) ABSTRACT

A vertical heat treatment apparatus for performing a film forming treatment on a plurality of target substrates having a surface with convex and concave portions includes: a gas supply unit that supplies a film forming gas into a reaction chamber; and gas distribution adjusting members made of quartz and installed to be positioned respectively above and below a region in which the plurality of target substrates held and supported by a substrate holding and supporting unit are disposed, wherein if S is a surface area per unit region of the gas distribution adjusting members and S0 is a surface area per unit region obtained by dividing a surface area of the target substrate by a surface area calculated based on an external dimension of the target substrate, a value obtained by dividing S by S0 (S/S0) is set to be 0.8 or more.

### CROSS-REFERENCE TO RELATED APPLICATION

This application claims the benefit of Japanese Patent Application No. 2014-047790, filed on Mar. 11, 2014, in the Japan Patent Office, the disclosure of which is incorporated herein in its entirety by reference.

### TECHNICAL FIELD

The present disclosure relates to a vertical heat treatment apparatus which forms films on all of a plurality of substrates, a method of operating the vertical heat treatment apparatus, and a non-transitory computer-readable recording medium storage medium for storing a program for performing the operating method.

### BACKGROUND

In general, a film forming treatment such as ALD (Atomic Layer Deposition) or CVD (Chemical Vapor Deposition) is performed on a semiconductor wafer (hereinafter, referred to as a wafer) composed of a silicon substrate, etc. in order to fabricate a semiconductor product. The film forming treatment may be performed in a batch type vertical heat treatment apparatus for treating a plurality of wafers at a time. In this case, the wafers are moved and mounted onto a vertical wafer boat so that they are supported in the shape of shelves in multi-stages on the wafer boat. The wafer boat is carried (loaded) into an evacuable reaction chamber (reaction tube) from below, and a variety of gases are then supplied into the reaction chamber in a state that the interior of the reaction chamber is airtightly sealed, thereby performing the film forming treatment on the wafers. A method of performing the CVD with wafers mounted on the wafer boat is known as prior art.

Dummy wafers are held and supported in upper and lower sides of the wafer boat, and a plurality of wafers (for convenience of explanation, which may be described as product wafers), which are target substrates for manufacturing the semiconductor products, is held and supported such that the product wafers are inserted between dummy wafers located in the upper and lower sides of the wafer boat. In such a state, the wafer boat is carried into the reaction chamber as described above. As such, the reason why the dummy wafers are held and supported along with the product wafers in the wafer boat is to form films with high uniformity on the product wafers by smoothing the gas flow in a treatment chamber and by increasing uniformity of temperature among the product wafers, and is to prevent particles from being entrained on the product wafers when particles are produced from the wafer boat made of quartz. Unlike the product wafers, various films for forming the semiconductor products are not formed on surfaces of the dummy wafers, and thus convex and concave portions for forming wiring are not formed. Hereinafter, the dummy wafer may be described as a bare wafer.

As a semiconductor product is being miniaturized, the convex and concave portions are formed with high density on a surface of a product wafer and thus a surface area of the product wafer is gradually increasing. For this reason, in the film forming treatment, the amount of gas consumed by the product wafer is gradually increasing as compared with the amount (reacted amount) of processing gas consumed by a bare wafer. Therefore, for product wafers respectively supported in upper and lower sections of a wafer boat, a relatively large amount of processing gas is supplied by disposing bare wafers, which consumes a small amount of processing gas, in the vicinity of such product wafers, so that. However, a larger amount of processing gas is consumed by product wafers that are supported above and below than the product wafers, which are supported in a middle section of the wafer boat. In this case, the product wafers supported in a middle section of the wafer boat consume a relatively small supply amount of processing gas per wafer. As a result, there is a concern that the thickness of films formed by the processing gas among the product wafers may vary.

In order to control the distribution of the processing gas for the product wafers, it was suggested that a film forming treatment is performed by CVD with dummy wafers mounted in a wafer boat. In this case, the dummy wafers are made of silicon and have a surface area approximately equal to that of a product wafer. Further, it was suggested that the dummy wafers are reused by immersing the dummy wafers in a hydrofluoric acid solution after the film formation process, thereby removing the formed film. However, such a configuration requiring such wet etching is disadvantageous in that the dummy wafers should be transferred from the vertical heat treatment apparatus to another apparatus, thereby causing a need for a great deal of labor.

### SUMMARY

Some embodiments of the present disclosure provide a technique that can improve uniformity of the film thicknesses among the substrates and save labor for operating an apparatus when performing a film forming treatment by supplying a processing gas into a reaction chamber with a holding and supporting unit for holding and supporting a plurality of substrates in the shape of shelves loaded into the reaction chamber.

According to one embodiment of the present disclosure, there is provided a vertical heat treatment apparatus for performing a film forming treatment on a plurality of target substrates by heating the target substrates with a heating unit in a state that the target substrates are held and supported by a substrate holding and supporting unit in a vertical reaction chamber, each of the target substrates having a surface with convex and concave portions, the apparatus comprising: a gas supply unit that supplies a film forming gas into the reaction chamber; and gas distribution adjusting members made of quartz and installed to be positioned respectively above and below a region in which the plurality of target substrates held and supported by the substrate holding and supporting unit are disposed, wherein if S is a surface area per unit region of the gas distribution adjusting members and S0 is a surface area per unit region obtained by dividing a surface area of the target substrate by a surface area calculated based on an external dimension of the target substrate, a value obtained by dividing S by S0 (S/S0) is set to be 0.8 or more.

According to another embodiment of the present disclosure, there is provided a method of operating a vertical heat treatment apparatus for performing a film forming treatment on a plurality of target substrates by heating the target substrates with a heating unit in a state that the target substrates are held and supported by a substrate holding and supporting unit in a vertical reaction chamber, each of the target substrates having a surface with convex and concave portions, the method comprising supplying a film forming gas into the reaction chamber by using a gas supply unit in a state that gas distribution adjusting members made of quartz are positioned respectively above and below a region in which the plurality of target substrates held and supported by the substrate holding and supporting unit are disposed, wherein if S is a surface area per unit region of the gas distribution adjusting members and S0 is a surface area per unit region obtained by dividing a surface area of the target substrate by a surface area calculated based on an external dimension of the target substrate, a value obtained by dividing S by S0 (S/S0) is set to be 0.8 or more.

According to another embodiment of the present disclosure, there is provided a non-transitory computer-readable storage medium for storing a program used in a vertical heat treatment apparatus in order to perform the aforementioned method.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional side view of a vertical heat treatment apparatus according to a first embodiment of the present disclosure.

FIG. 2 is a cross sectional plan view of the vertical heat treatment apparatus.

FIG. 3 is a longitudinal sectional side view of a product wafer.

FIG. 4 is a timing chart of treatment of the vertical heat treatment apparatus.

FIG. 5 is a view illustrating a process in which a film is formed on the product wafer in the first embodiment.

FIG. 6 is a view illustrating a process in which a film is formed on the product wafer in a comparative example.

FIG. 7 is a graph showing the distribution of film thickness among wafers treated in the vertical heat treatment apparatus.

FIG. 8 is a view illustrating an example that product wafers are arranged in a wafer boat.

FIG. 9 is a longitudinal sectional side view of a vertical heat treatment apparatus according to a second embodiment.

FIG. 10 is a cross sectional plan view of the vertical heat treatment apparatus.

FIG. 11 is a graph showing the distribution of film thickness among wafers treated in the vertical heat treatment apparatus.

FIG. 12 is a graph showing the distribution of film thickness among wafers treated by using a wafer boat according to a third embodiment.

FIG. 13 is a graph showing the distribution of film thickness among wafers treated by using a wafer boat according to a fourth embodiment.

FIG. 14 is a view illustrating configuration of an injector used in an evaluation test.

FIG. 15 is a graph showing results of the evaluation test.

### DETAILED DESCRIPTION

Hereinafter, some embodiments of the present disclosure will be described with reference to the accompanying drawings. Throughout the drawings, like reference numerals are used to designate like elements. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

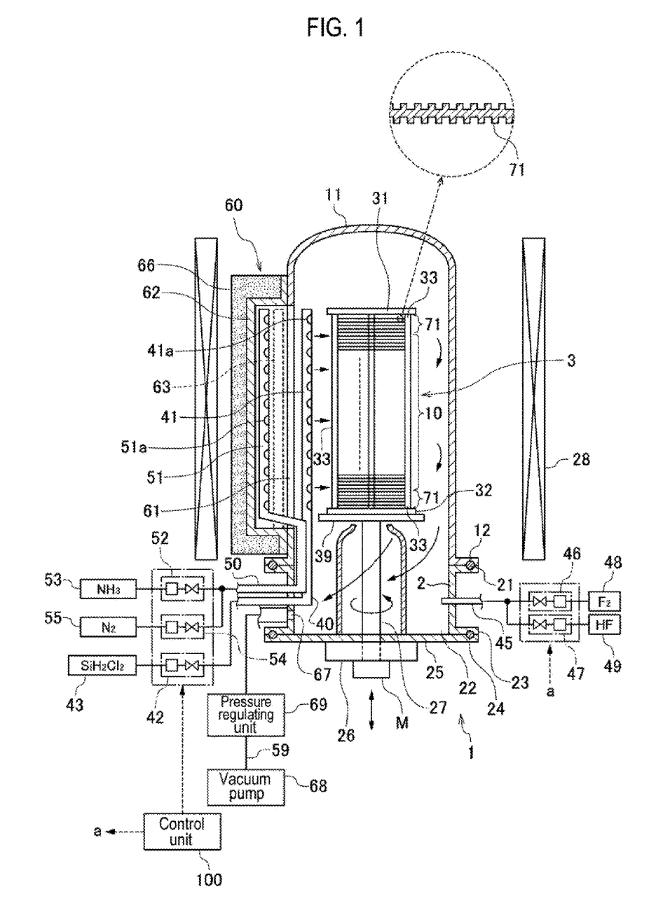

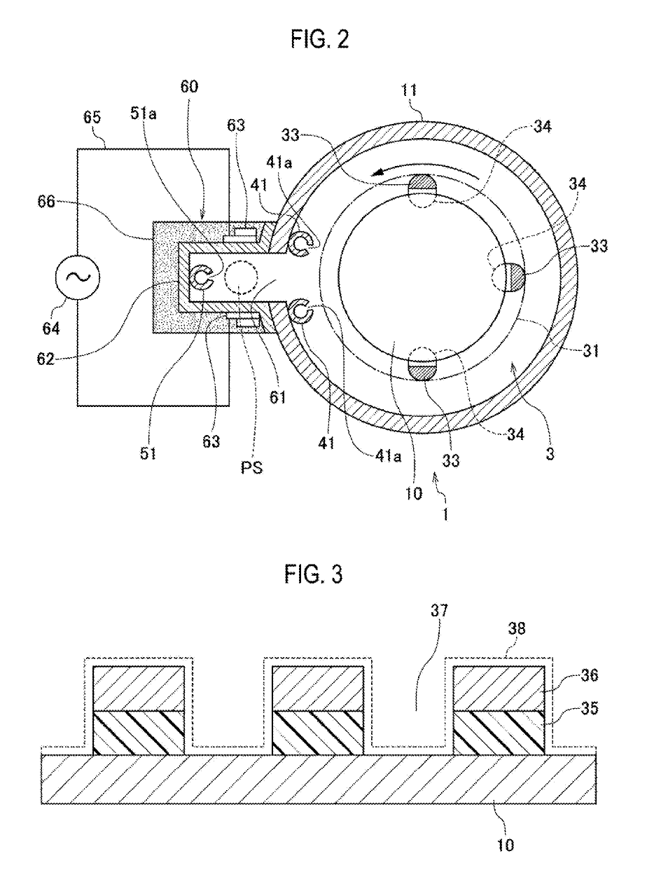

A first embodiment of the present disclosure will be described based on the accompanying drawings. FIGS. 1 and 2 are schematic longitudinal and cross sectional views of a vertical heat treatment apparatus 1 according to the present disclosure, respectively. Reference numeral 11 in FIGS. 1 and 2 designates a reaction tube which, for example, forms a treatment chamber made of quartz in the shape of a vertical cylinder. In addition, a peripheral portion of a lower end opening of the reaction tube 11 is formed integrally with a flange 12. A manifold 2, for example, which is formed of stainless steel in the shape of a cylinder, is connected to a lower surface of the flange 12 with a sealing member 21 such as an O-ring interposed therebetween.

A lower end of the manifold 2 is open as a loading/unloading opening (furnace opening), and a peripheral portion of the opening 22 is formed integrally with a flange 23. In a lower portion of the manifold 2, a lid 25 made of, e.g., quartz, is installed to be opened and closed in a vertical direction by a boat elevator 26. The lid 25 airtightly closes the opening 22 on the lower surface of the flange 23 with a sealing member 24 such as an O-ring interposed therebetween. A rotating shaft 27 is installed to penetrate a central portion of the lid 25. A wafer boat 3 that is a substrate holding and supporting unit is mounted on an upper end of the rotating shaft with a stage 39 interposed therebetween.

An L-shaped first raw material gas supply pipe 40 is inserted through a sidewall of the manifold 2. At a leading end of the first raw material gas supply pipe 40, as shown in FIG. 2, two first raw material gas supply nozzles 41, which are made of quartz pipes extending upward in the reaction tube 11, are disposed with an elongated opening 61 of a plasma generating unit 60 described later interposed therebetween. A plurality (large number) of gas discharge holes 41a are formed at a predetermined interval in a lengthwise direction of the first raw material gas supply nozzles 41. A gas can be approximately uniformly discharged from the respective gas discharge holes 41a in a horizontal direction. In addition, a supply source 43 of a silane-based gas, which is a first raw material gas, such as SiH₂Cl₂ (dichlorosilane: DCS) gas, is connected to a base end of the first raw material gas supply pipe 40 via a supply device group 42.

Further, an L-shaped second raw material gas supply pipe 50 is inserted through the sidewall of the manifold 2. A second raw material gas supply nozzle 51 made of quartz is installed at a leading end of the second raw material gas supply pipe 50. The second raw material gas supply nozzle 51 extends upward in the reaction tube 11, is bent while extending upward and is installed in the plasma generating unit 60 described later. A plurality (large number) of gas discharge holes 51a are formed at a predetermined interval in a lengthwise direction of the second raw material gas supply nozzle 51. A gas can be approximately uniformly discharged from the respective gas discharge holes 51a in a horizontal direction. In addition, a base end of the second raw material gas supply pipe 50 is bifurcated into two branches so that a supply source 53 of NH₃ (ammonia) gas that is a second raw material gas is connected to one branch of the second raw material gas supply pipe 50 via a supply device group 52, and a supply source 55 of N₂ (nitrogen) gas is connected to the other branch of the second raw material gas supply pipe 50 via a supply device group 54.

Moreover, one end of a cleaning gas supply pipe 45 is inserted through a sidewall of the manifold 2. The other end of the cleaning gas supply pipe 45 is bifurcated into two branches which in turn are connected to a gas supply source 48 of F₂ (fluorine) gas and a gas supply source 49 of HF (hydrogen fluoride) via supply device groups 46 and 47, respectively. Thus, a mixed gas of F₂ and HF may be supplied as a cleaning gas into the reaction tube 11. The cleaning gas is not limited to a gas employing such fluorine gas or hydrogen fluoride gas as a major component, but may be, for example, a gas employing another fluorine compound as a major component. Furthermore, each of the supply device groups 42, 46, 47, 52 and 54 is comprised of a valve, a flow rate adjuster, and the like.

Further, the plasma generating unit 60 is provided on a portion of the sidewall of the reaction tube 11 in a height direction of the reaction tube. The plasma generating unit 60 is constructed in a manner that the vertically elongated opening 61 is formed by vertically cutting out the sidewall of the reaction tube 11 by a predetermined width and a vertically elongated compartment wall 62 made of, e.g., quartz, which is concave in cross section, is then airtightly welded on an outer wall of the reaction tube 11 to cover the opening 61. A region surrounded by the compartment wall 62 becomes a plasma generating region PS.

The opening 61 is formed to be sufficiently long in the vertical direction in order to cover all of wafers, which are held and supported by the wafer boat 3, in the height direction. Further, a pair of elongated plasma electrodes 63 facing each other in the lengthwise direction (vertical direction) is provided on outer surfaces of both sidewalls of the compartment wall 62. A high frequency power source 64 for plasma generation is connected to the plasma electrodes 63 via a power supplying line 65. Plasma can be generated by applying a high frequency voltage of, for example, 13.56 MHz to the plasma electrodes 63. An insulating protection cover 66 made of, for example, quartz is installed to cover the compartment wall 62 at the outside of the compartment wall 62.

Further, an exhaust port 67 is open in the manifold 2 to make the atmosphere in the reaction tube 11 be vacuum-exhausted. The exhaust port 67 is connected to an exhaust pipe 59, which has a vacuum pump 68 constituting a vacuum evacuating means for depressurizing and evacuating the interior of the reaction tube 11 to a desired degree of vacuum, and a pressure regulating unit 69 comprised of, for example, a butterfly valve. As shown in FIG. 1, a cylindrical heater 28, which is a heating means for heating the reaction tube 11 and wafers in the reaction tube 11, is also installed to surround the outer circumference of the reaction tube 11.

Further, the vertical heat treatment apparatus 1 includes a control unit 100. The control unit 100 is comprised of, for example, a computer and configured to control the boat elevator 26, the heater 28, the supply device groups 42, 46, 47, 52 and 54, the high frequency power source 64, the pressure regulating unit 69, and the like. More specifically, the control unit 100 includes a memory unit configured to store sequence programs for performing a series of treatment steps, which will be described later, carried out in the reaction tube 11, a means for reading out instructions of the respective programs and outputting control signals to the respective components, and the like. Moreover, the programs are stored in the control unit 100 in a state that they are stored in a storage medium such as a hard disk, a flexible disk, a compact disk, a magneto-optical (MO) disk, a memory card or the like.

Next, the wafer boat 3 will be further explained. The wafer boat 3 is made of quartz, and includes a ceiling plate 31 and a bottom plate 32 which are placed parallel to each other during a film forming treatment. The ceiling plate 31 and the bottom plate 32 are respectively connected to one end and the other end of each of three pillars 33 extending in the vertical direction. Supports 34 (see FIG. 2) are provided in multi-stages for each of the pillars 33 in order to horizontally hold and support wafers on the supports 34. Thus, wafers are held and supported in the shape of shelves in multi-stages in the wafer boat 3. A region where a wafer is supported on each of the supports 34 is referred to as a slot, and 120 slots are provided in this example. In addition, the respective slots are designated by numbers 1 to 120, and a smaller number is assigned to a slot positioned closer to an upper end.

In the first embodiment, wafers 10 and wafers 71 are mounted in the slots. The wafer 10 is a product wafer for manufacturing a semiconductor product described in the BACKGROUND, and is made of, for example, a silicon substrate. As shown in FIG. 3, convex and concave portions for forming wiring are formed on a surface of the wafer 10. In this figure, the reference numeral 35 designates a polysilicon film, and the reference numeral 36 designates a tungsten film. The reference numeral 37 is a concave portion formed in the films 35 and 36. The reference numeral 38 is a SiN film (silicon nitride film) formed by the vertical heat treatment apparatus 1.

The wafer 71 is a wafer made of quartz (hereinafter, referred to as a quartz wafer). The quartz wafer 71 is configured to have a contour corresponding to that of the wafer 10 when seen from the top, so as to be mounted in the wafer boat 3. In order to prevent the wafer from breaking during handling, the thickness of the quartz wafer 71 is, for example, slightly greater than that of the wafer 10 and is, for example, 2 mm. A longitudinal sectional side view of the quartz wafer 71 is shown in an enlarged scale within a dotted-line circle depicted at the end of a dotted-line arrow of FIG. 1. As shown herein, convex and concave portions are formed in front and back sides of the quartz wafer 71. The convex and concave portions are formed by laser processing, mechanical machining, or the like.

A surface area per unit region, which is obtained by dividing the surface area of the wafer 10 by a surface area calculated based on an external dimension of the wafer 10, is referred to as S0. The surface area obtained based on the external dimension is a virtual surface area obtained by assuming that the surfaces of the wafer 10 are flat surfaces without considering concave portions 37 of the surface of the wafer 10. That is, a value obtained by dividing the actual surface area of the wafer 10 by the virtual surface area is the surface area per unit region S0. The surface area of the wafer, which is referred to herein, is the area of a top side (front side) of the wafer+the area of a bottom side (back side) of the wafer. In addition, a surface area per unit region, which is obtained by dividing the surface area of the quartz wafer 71 by a surface area calculated based on external dimension of the quartz wafer 71, is referred to as S. In the same manner as the wafer 10, the surface area obtained based on the external dimension of the quartz wafer 71 is a virtual surface area obtained by assuming that the front and back sides of the quartz wafer 71 are flat surfaces without considering concave portions formed in the front and back sides of the quartz wafer 71. In order to adjust a gas distribution in the vertical direction in the wafer boat 3 as described later, S/S0 is set to be 0.8 or more. In this example, the quartz wafer 71 is configured such that S/S0=1.

As shown in FIG. 1, the quartz wafers 71 are held and supported in a plurality of slots at upper and lower sections among the slots of the wafer boat 3. The wafers 10 are held and supported in slots in which the quartz wafers 71 are not held and supported. Thus, a group of wafers is held and supported by the wafer boat 3 such that it is inserted between above and below quartz wafers 71. In the same manner as the wafers 10, the quartz wafers 71 may be configured to be detachably attached to or to be fixed to the wafer boat 3. The wafers 10 are transferred to and mounted in the wafer boat 3 by a transferring/mounting mechanism (not shown). If the quartz wafers 71 are configured to be detachably attached to the wafer boat 3, the quartz wafers are transferred and mounted, for example, by the transferring/mounting mechanism, in the same manner as the wafers 10. In this example, the quartz wafers 71 are fixed to the wafer boat 3 for easy handling.

Next, the film forming treatment performed in the vertical heat treatment apparatus 1 will be described. First, the wafer boat 3 mounted with the group of wafers 10 inserted between the above and below quartz wafers 71 as described above is lifted from below and is carried (loaded) into the reaction tube 11 which was previously set to a predetermined temperature. The lower opening 22 of the manifold 2 is closed by the lid 25, thereby hermetically sealing the interior of the reaction tube 11.

Then, the interior of the reaction tube 11 is vacuum-evacuated by the vacuum pump 68 to a predetermined degree of vacuum. Subsequently, the pressure in the reaction tube 11 becomes, for example, 665.5 Pa (5 Torr), and DCS gas and N₂ gas are supplied into the reaction tube 11 from the first raw material gas supply nozzles 41, for example, respectively at flow rates of 1,000 sccm and 2,000 sccm, for example, for three seconds in a state that the high frequency power source 64 is turned off. Thus, molecules of the DCS gas are adsorbed onto a surface of each of the wafers 10 held and supported in the shape of shelves in the rotating wafer boat 3 (Step S1).

Thereafter, the supply of the DCS gas is stopped. The N₂ gas is continuously supplied into the reaction tube 11 and the pressure in the reaction tube 11 becomes, for example, 120 Pa (0.9 Torr), thereby purging the interior of the reaction tube 11 with the N₂ gas (Step S2). Then, while the pressure in the reaction tube 11 becomes, for example, 54 Pa (0.4 Torr), NH₃ gas and N₂ gas are supplied into the reaction tube 11 from the second raw material gas supply nozzle 51, for example, respectively at flow rates of 5,000 sccm and 2,000 sccm, for example, for 20 seconds in a state that the high frequency power source 64 is turned on (Step S3). Thus, active species, such as N radicals, H radicals, NH radicals, NH₂ radicals, and NH₃ radicals, react with the molecules of the DCS gas, thereby generating a SiN film 38 shown in FIG. 3.

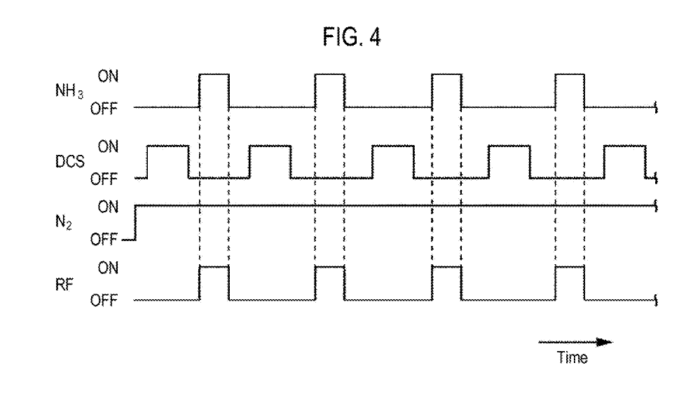

Thereafter, the supply of the NH₃ gas is stopped. The N₂ gas is continuously supplied into the reaction tube 11 and the pressure in the reaction tube 11 becomes, for example, 106 Pa (0.8 Torr), thereby purging the interior of the reaction tube 11 with the N₂ gas (Step S4). FIG. 4 is a timing chart illustrating a timing at which each gas is supplied and a timing at which the high frequency power source 64 is turned on. As shown in this chart, by repeating Steps S1 to S4 plural times, e.g., 200 times, a thin SiN film 38 are laminated on a layer-by-layer basis and grown on the surface of the wafer 10, thereby forming the SiN film 38 having a desired thickness on the surface of the wafer 10.

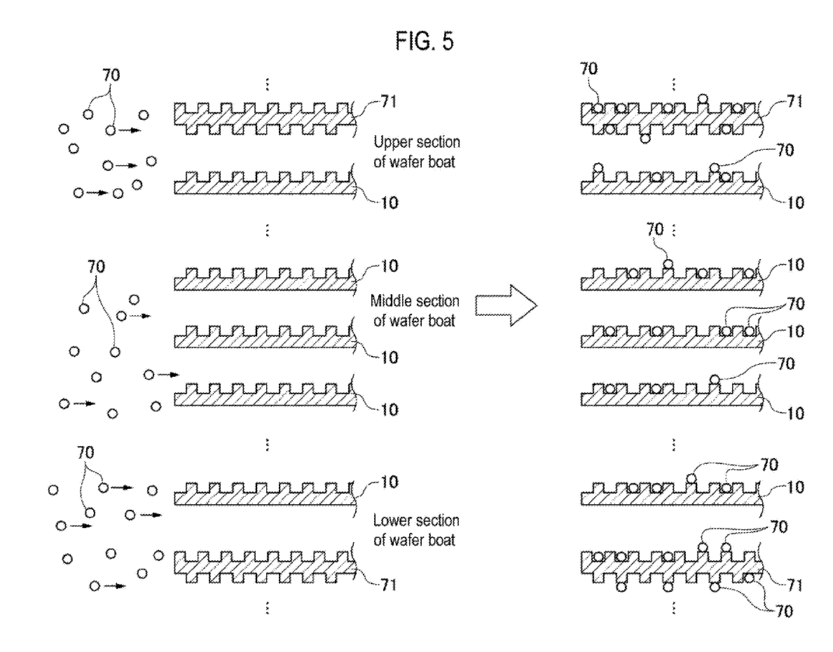

The status of the wafer 10 and quartz wafer 71 when the DCS gas is supplied during the film forming treatment will be described using a schematic view of FIG. 5. In this figure, the reference numeral 70 designates molecules of the DCS gas. In a middle section of the wafer boat 3, the wafers 10 having large surface areas by forming a surface with convex and concave portions are disposed in multi-stages, and the molecules 70 supplied to the middle section of the wafer boat 3 are consumed for (adsorbed onto) the wafers 10. As such, the molecules 70 are consumed such that they are distributed with high uniformity among the wafers 10. Thus, the absorption amount of the molecules 70 per sheet of the wafer 10 is prevented from being excessive.

Similarly to the wafers 10 held and supported in the middle section, wafers having large surface areas, i.e., quartz wafers 71, exist in the vicinity of the wafers 10 held and supported in upper and lower sections of the wafer boat 3. Thus, the molecules 70 supplied to the upper and lower sections of the wafer boat 3 are consumed such that they are distributed with high uniformity on the wafers 10 and the quartz wafers 71. That is, the adsorption amount of molecules 70 onto the quartz wafer 71 is relatively large due to the large surface area of the quartz wafer 71. Thus, it is possible to prevent excessive molecules 70 from being supplied to the wafer 10, thereby suppressing an excessive absorption amount of molecules 70 per sheet of the wafer 10.

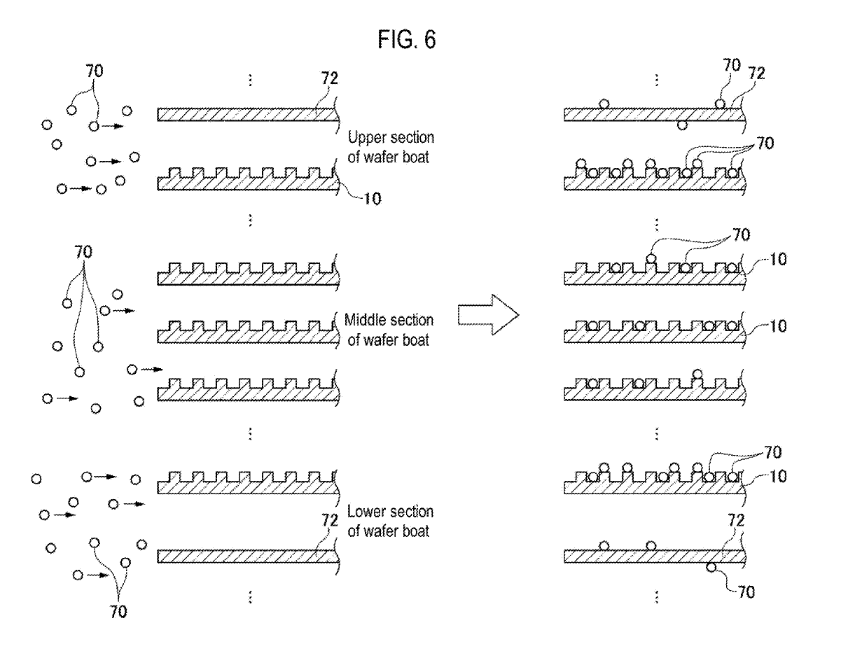

FIG. 6 shows a schematic view for the purpose of comparison with FIG. 5. FIG. 6 illustrates a state that the molecules 70 are adsorbed onto the wafers 10 when performing a treatment by disposing a bare wafer 72 described in the BACKGROUND, instead of the quartz wafer 71, into each slot in which the quartz wafer 71 described above is disposed. As previously explained above, the bare wafer 72 is made of, for example, silicon. Since the bare wafer 72 does not have any convex and concave portions for forming a device on its surfaces, it has a small surface area. Even in a case where the bare wafers 72 are disposed, as described in FIG. 5, the molecules 70 are distributed onto each of the wafers 10 in the middle section of the wafer boat 3, thereby suppressing the absorption amount of molecules 70 per sheet of the wafer 10. However, for the wafers 10 held and supported in the upper and lower sections of the wafer boat 3, the bare wafers 72 exist in the vicinity of the wafers 10 and they have a small amount of adsorption of molecules 70 due to small surface areas. Thus, surplus molecules 70 that are not consumed at the bare wafers 72 are adsorbed onto the wafers 10.

As illustrated in FIGS. 5 and 6, because the quartz wafers 71 are held and supported by the wafer boat 3, the molecules 70 are prevented from being excessively absorbed onto the wafers 10 at the upper and lower sections of the wafer boat. As a result, the molecules 70 are adsorbed with high uniformity among the wafers. Although the example in which the molecules 70 of the DCS gas are adsorbed has been described, the quartz wafers 71 held and supported by the wafer boat 3 also allow radicals generated from NH₃ and N₂ gases to be supplied with high uniformity among the wafers 10, as the molecules 70. In addition, the supplied radicals react with the molecules 70.

After the process is terminated by repeating Steps S1 to S4 200 times as described above, the wafer boat 3 is unloaded from the reaction tube 11. After the wafers 10 for which the film formation treatment is terminated are taken out from the wafer boat 3, the wafer boat 3 is again loaded into the reaction tube 11 and the opening 22 is closed. The interior of the reaction tube 11 is vacuum-evacuated and is set to a predetermined pressure, while setting the interior temperature of the reaction tube 11 to, for example, 350 degrees C. Then, the aforementioned cleaning gas composed of F₂ and HF is supplied into the reaction tube 11. Accordingly, the SiN film 38 formed in the reaction tube 11 and on the wafer boat 3 and quartz wafers 71 are etched and removed from the reaction tube 11 through entrainment in an exhaust stream. Thereafter, the supply of the cleaning gas is stopped, and the wafer boat 3 is unloaded from the reaction tube 11. Then, subsequent wafers 10 are mounted in the wafer boat 3, and the film forming treatment is performed on the subsequent wafers 10 according to Steps S1 to S4.

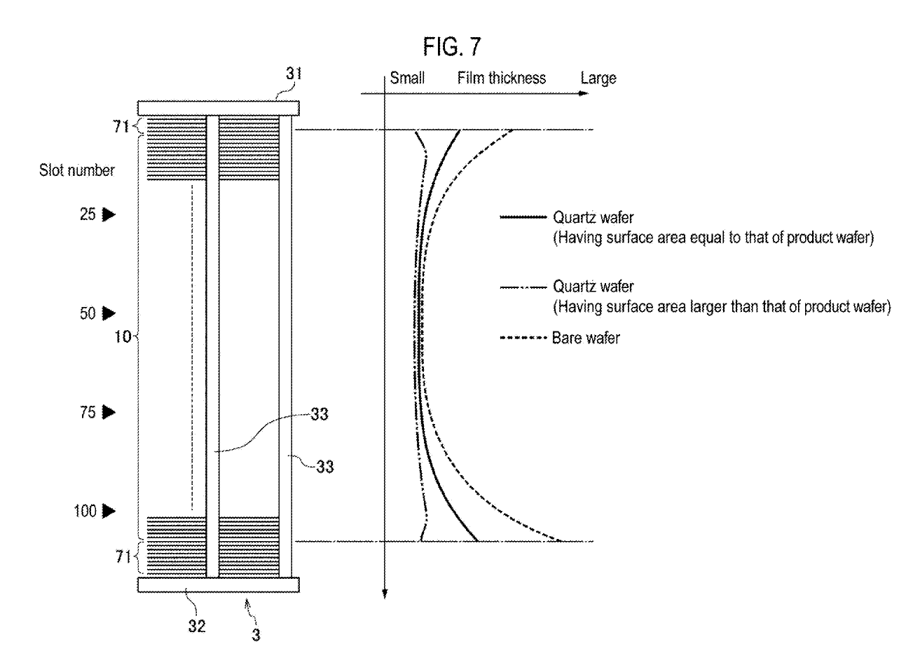

FIG. 7 shows a graph illustrating relationships between film thicknesses of the wafers 10 and positions of the slots. The abscissa axis of the graph corresponds to the film thicknesses of the wafers 10, and the ordinate axis of the graph corresponds to the positions of the slots. Slot numbers are assigned to the wafer boat 3 such that the heights of the slots correspond to scales of the ordinate axis of the graph. A curve indicated by a dotted line represents data obtained based on an experiment, and shows a film thickness distribution of the wafers 10 in the respective slots when the film forming treatment is performed by holding and supporting the bare wafers 72, instead of the quartz wafer 71, in the wafer boat 3 as described in FIG. 6. For the reason described with reference to FIG. 6, the film thicknesses of the wafers 10 gradually increase from the slots in the middle section of the wafer boat 3 toward the slots at the upper and lower sections. Hence, differences in film thickness between the wafers 10 in the slots in the upper and lower sections and the wafers 10 in the slots in the middle section are relatively large. That is, a variation in film thickness among the slots is large. Further, in the wafer boat 3 in FIG. 7, there is shown a state of holding and supporting the quartz wafers 71 according to an embodiment, not the bare wafers 72.

A curve indicated by a solid line in FIG. 7 is a curve of the case that the film forming treatment is performed by disposing the quartz wafers 71 as illustrated in FIGS. 1 to 5, and shows the effect of the first embodiment. For the reason described with reference to FIG. 5, excessive supply of a gas to the wafers 10 at the upper and lower sections of the wafer boat 3 is suppressed by the quartz wafers 71. Thus, as shown in the curve, an increase in the film thickness of each of the wafers 10 at the upper and lower sections is suppressed. As a result, it is possible to improve the uniformity of film thicknesses among the wafers 10 in the slots.

As the surface areas of the quartz wafers 71 become larger, it is believed that the supply of a gas to the wafers 10 at the upper and lower sections of the wafer boat 3 can be suppressed. In FIG. 7, a curve indicated by a two-dot chain line is a curve of a film thickness distribution in a case that the surface areas of the quartz wafers 71 are greater than those of the wafers 10. The surface areas of the quartz wafers 71 are determined to have an appropriate film thickness distribution depending on the surface areas of the wafers 10. Even when only one quartz wafer 71 is provided at each of the upper and lower sections of the wafer boat 3, a gas distribution for the wafers 10 can be adjusted as described above. However, it is preferable to provide a plurality of quartz wafers in view of controlling a temperature distribution among the wafers 10.

Further, since the quartz wafer 71 is made of quartz, corrosion, which is caused by the cleaning gas including the fluorine gas or a gas composed of a fluorine compound, is suppressed as compared to a wafer made of Si. For this reason, the quartz wafer 71 can be repeatedly used in the film forming treatment as described above. Further, since it is unnecessary to transfer the quartz wafer 71 to an apparatus for performing wet etching in order to perform cleaning, it is possible to save labor for operating such an apparatus.

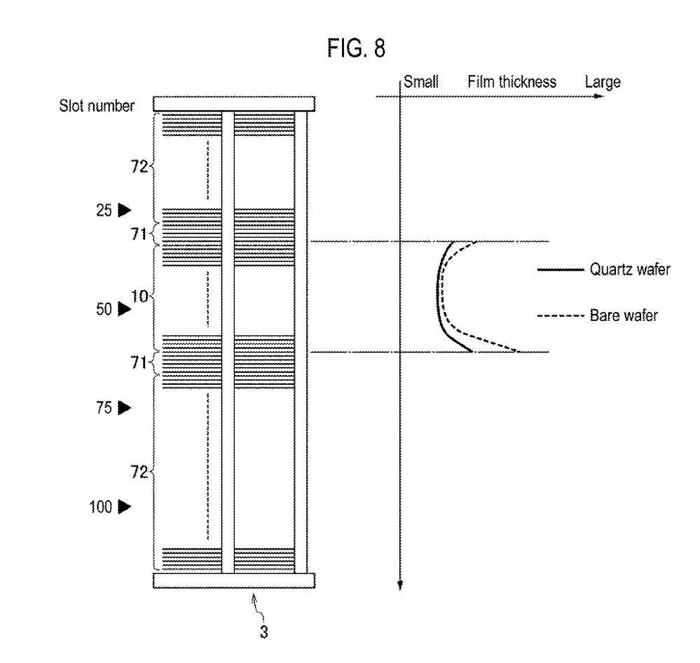

Meanwhile, there is a case that the film forming treatment is performed with a relatively small number of wafers 10 held and supported in the wafer boat 3. In this case, for example, the film forming treatment is performed by holding and supporting the wafers 10 as shown in FIG. 8. Specifically, the wafers 10 are held and supported in slots in the middle section. In the example of FIG. 8, the wafers 10 are consecutively mounted in slots around Slot Nos. 35 to 60. Then, the quartz wafers 71, e.g., a plurality of quartz wafers, are held and supported in slots respectively above and below Slot Nos. 35 to 60. In the example shown in FIG. 8, about 5 quartz wafers 71 are held and supported in the slots respectively above and below the slots with the wafers 10 held and supported.

The bare wafers 72 are held and supported in slots respectively at the upper and lower sections of the wafer boat 3 so that the group of quartz wafers 71 and the group of wafers 10 are inserted between the bare wafers. The bare wafers 72 are mounted to prevent disturbance of the flow of a gas in the reaction tube 11 or distortion of the temperature distribution in the wafers 10. As such, any one of the wafers 10, the quartz wafers 71 and the bare wafers 72 is held and supported in each of Slot Nos. 1 to 120.

Similarly to FIG. 7, FIG. 8 also is a graph showing a film thickness distribution. A curve indicated by a solid line shows a film thickness distribution of the wafers 10 when performing a film forming treatment on the wafers 10 with the quartz wafers 71 mounted in the wafer boat 3 as described above. A curve indicated by a dotted line shows a film thickness distribution of the wafers 10 when performing a film forming treatment by holding and supporting the bare wafers 72, instead of the quartz wafers 71, in the above explained slots in which the quartz wafers 71 are held and supported. As illustrated in the graph of FIG. 8, the quartz wafers 71 can be mounted in the wafer boat 3 as described above even when the film forming treatment is performed on a small number of wafers 10. For the reason illustrated with reference to FIGS. 5 and 6, it is possible to prevent an increase in the film thickness of each of the wafers 10, which are at the upper and lower sections of the wafer boat 3, in the group of wafers 10 mounted in the wafer boat 3. As a result, it is possible to improve uniformity of film thicknesses among the wafers 10.

### Second Embodiment

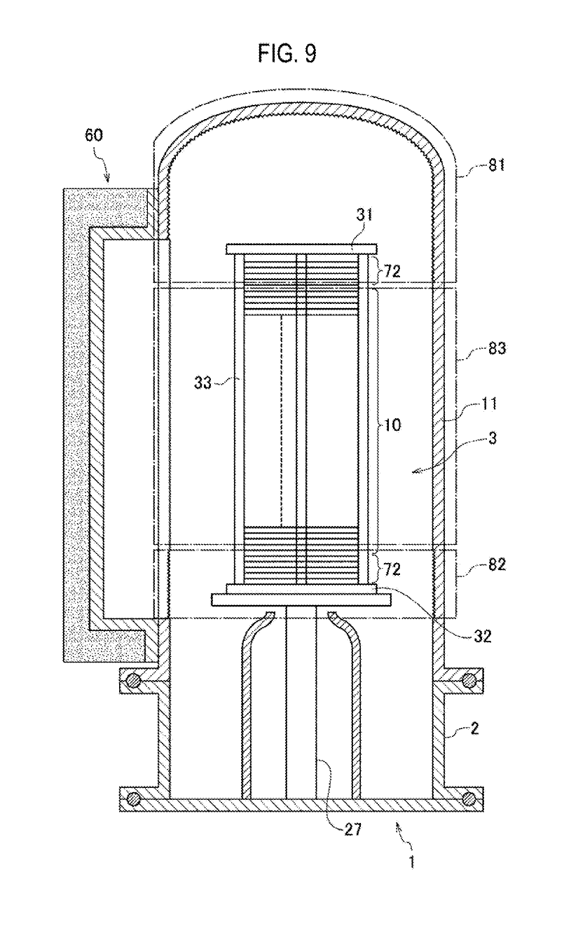

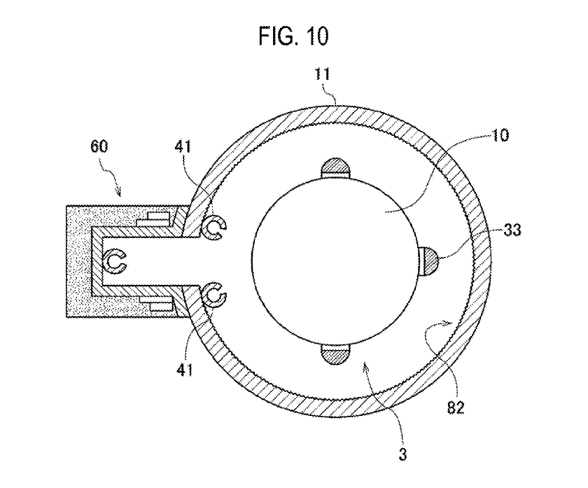

As explained in FIG. 5, if there are members having relatively large surface areas above and below a group of wafers 10 mounted in the wafer boat 3, it is possible to adjust the film thickness distribution among the wafers 10 by reducing the supply amounts of the gas above and below the group of wafers 10. Thus, the member for adjusting gas distribution is not limited to the quartz wafer 71. FIGS. 9 and 10 show a longitudinal sectional side view and a cross sectional plan view of a vertical heat treatment apparatus 1 according to a second embodiment, respectively. A vertical heat treatment apparatus 1 according to the second embodiment is different from that of the first embodiment as to the configuration of the reaction tube 11 but the other components are constructed in the same manner. In FIGS. 9 and 10, some of the members described in the first embodiment are omitted.

In the vertical heat treatment apparatus 1 according to the second embodiment, convex and concave portions are formed in an upper region 81 including a ceiling surface and an upper circumferential surface of the reaction tube 11 and in a lower region 82 that is a lower circumferential surface of the reaction tube 11, in order to increase the surface areas. The upper and lower regions 81 and 82 are inner circumferential surfaces of the reaction tube 11. When the wafer boat 3 is accommodated in the wafer boat 3, the lower region 82 includes a region lower than the group of wafers 10 mounted in the wafer boat 3. The convex and concave portions of the upper and lower regions 81 and 82 are formed, for example, by means of a sandblasting treatment or a chemical solution treatment. If the sandblasting treatment is performed, arithmetic average roughness (Ra) is, for example, 0.4 to 4.0 μm. If the chemical solution treatment is performed, the arithmetic average roughness (Ra) is, for example, 0.3 to 4.0 μm. Convex and concave portions may be formed also in the quartz wafer 71 according to the first embodiment by means of the sandblasting or chemical solution treatment. Further, in the same manner as the quartz wafer 71, convex and concave portions may be formed in the reaction tube 11 by laser processing.

By forming roughness (convex and concave portions) as described above, the upper and lower regions 81 and 82 serve to adjust supply distribution of a gas in the same manner as quartz wafer 71 according to the first embodiment. To this end, if a surface area per unit region for each of the upper and lower regions 81 and 82 is S, the convex and concave portions are formed such that the relationship S/S0 with the surface area S0 per unit region of the wafer 10 becomes 0.8 or more as in the first embodiment. The surface area of each of the upper and lower regions 81 and 82 is a surface area of a surface facing the treatment space into which a gas is supplied. To further explain the surface area S per unit region of the upper region 81 in detail as an example, it is assumed that the upper region 81 has no convex and concave portions and is cut to obtain a segment having an area A equal to the area of a region surrounded by the contour of the wafer 10. If the surface area of a surface of the cut segment facing the treatment space in the reaction tube 11 is B, S is B/A. The surface area B is a surface area measured under the assumption that there are convex and concave portions. The surface area S of the lower region 82 is calculated in the same manner.

In the inner circumferential surface of the reaction tube 11, a region interposed between the upper and lower regions 81 and 82 is referred to as a middle region 83. The middle region 83 is positioned around an outer periphery of the group of wafers 10 when the wafer boat 3 is loaded into the reaction tube 11. The middle region 83 is configured to have a smooth surface without performing the sandblasting or chemical solution treatment. That is, the roughness of the middle region 83 is smaller than that of the upper and lower regions 81 and 82.

The film forming treatment and cleaning treatment are performed also in the vertical heat treatment apparatus 1 according to the second embodiment in the same manner as the first embodiment. By forming the rough inner circumferential surface of the reaction tube 11 as described above, a gas supplied into upper and lower sections of the wafer boat 3 during the film forming treatment is consumed in the upper and lower regions 81 and 82. Accordingly, as in the first embodiment, it is possible to prevent the gas from being excessively supplied to the wafers 10 held and supported at the upper and lower sections of the wafer boat 3. As such, the upper and lower regions 81 and 82 of the reaction tube 11 perform the same function as the quartz wafers 71 of the first embodiment as described above. Hence, unlike the first embodiment, the bare wafers 72, instead of the quartz wafers 71, are detachably held and supported by the wafer boat 3 in this embodiment. That is, the group of wafers 10 is held and supported such that it is inserted between above and below bare wafers 72. Unlike a case using the quartz wafers 71, the bare wafers 72 are removed from the wafer boat 3 during the cleaning treatment.

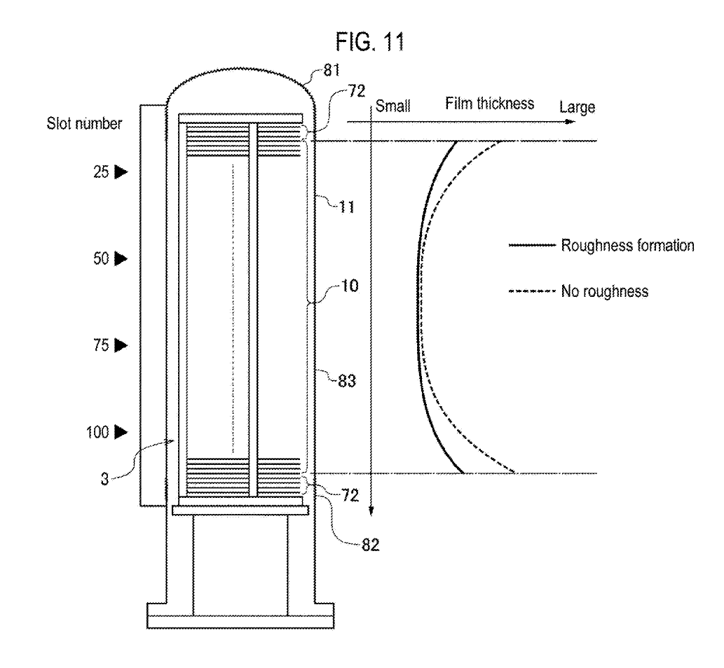

Similarly to FIG. 7, FIG. 11 shows a film thickness distribution of the wafers 10 in the respective slots. In this figure, a curve indicated by a dotted line shows a film thickness distribution of the wafers 10 when the film forming treatment is performed without forming the roughness to the reaction tube 11. A curve indicated by a solid line shows a film thickness distribution among the wafers 10 when the film forming treatment is performed by forming the roughness in the upper region 81 and lower region 82 as described above. As illustrated in the graph, by forming the roughness in the reaction tube 11, a gas is prevented from being excessively supplied to the wafers 10, which are at the upper and lower sections of the wafer boat 3, in the group of wafers 10 held and supported by the wafer boat 3, thereby improving uniformity of the film thicknesses among the wafers 10, as in the first embodiment.

A region formed with the roughness above the group of wafers 10 in the reaction tube 11 may be either of the ceiling surface and the side circumferential surface. For a region below the group of wafers 10 in the reaction tube 11, the roughness formation is not limited to forming the roughness in the side circumferential surface but the roughness may be made in a surface of the bottom plate of the reaction tube 11, i.e., a surface of the lid 25.

### Third Embodiment

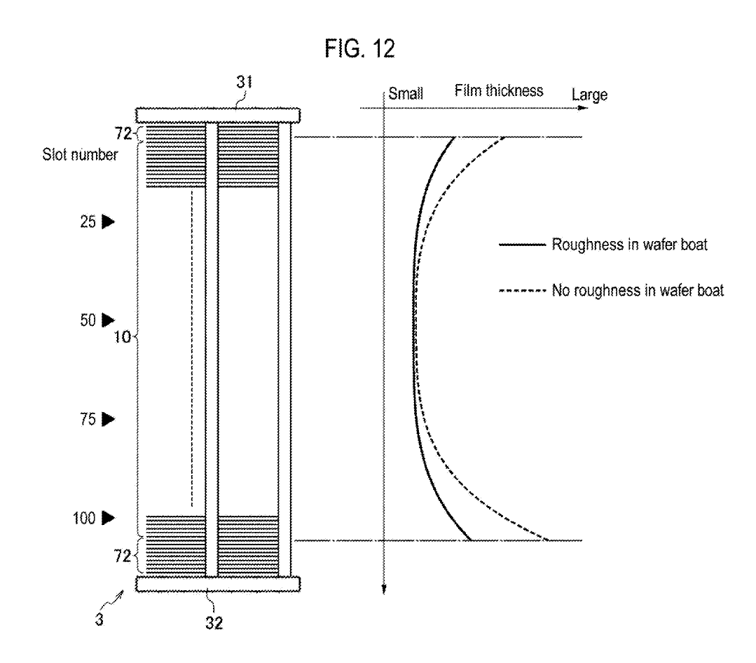

In the third embodiment, a vertical heat treatment apparatus 1 similar to that of the first embodiment is used, but the roughness described in the second embodiment is not formed, for example, in the inner surface of the reaction tube 11. Instead, the surface of each of the ceiling plate 31 and the bottom plate 32 of the wafer boat 3 is roughened as in the upper and lower regions 81 and 82 of the reaction tube 11 described in the second embodiment, resulting in the surface area S per unit region thereof/the surface area per unit region S0 of the wafer 10≧0.8. FIG. 12 shows a wafer boat 3 in which the roughness is formed as described above. For example, in the same manner as the second embodiment, a film forming treatment is performed with the wafers 10 and the bare wafers 72 mounted in the wafer boat 3. During the film forming treatment, the ceiling plate 31 and the bottom plate 32 perform the same function as the quartz wafers 71 described in the first embodiment and the upper and lower regions 81 and 82 of the reaction tube 11 described in the second embodiment, thereby adjusting the film thickness distribution among the wafers 10.

To explain the surface area S per unit region of the ceiling plate 31 of the wafer boat 3 in detail, it is assumed that the ceiling plate 31 has no convex and concave portions and is cut to obtain a segment having an area A equal to that of a region surrounded by the contour of the wafer 10. If the surface area of a surface of the cut segment which faces the treatment space in the reaction tube 11 is B, S is B/A. Since both upper and lower surfaces of the ceiling plate 31 face the treatment space, the surface area B is the sum of surface areas of the upper and lower surfaces. The surface area S per unit region of the bottom plate 32 of the wafer boat 3 is calculated in the same manner. The lower surface of the bottom plate 32 is covered by a stage 39 (see FIG. 1) for supporting the wafer boat and does not face the treatment space. Thus, the surface area B becomes the surface area of the upper surface.

The graph of FIG. 12 shows a relationship between film thicknesses and slots of the wafers 10, as in the graphs of the other figures. A curve indicated by a dotted line shows a film thickness distribution among the wafers 10 when the film forming treatment is performed without forming the roughness in the ceiling plate 31 and the bottom plate 32. A curve indicated by a solid line shows a film thickness distribution among the wafers 10 when the film forming treatment is performed in the wafer boat 3 formed with the roughness.

### Fourth Embodiment

In the fourth embodiment, the same vertical heat treatment apparatus as that of the first embodiment is used, and the wafer boat 3 is configured in the same manner as the first embodiment. In the fourth embodiment, wafers 10 and bare wafers 76 are held and supported in the wafer boat 3. The bare wafer 76 is configured to have the same shape as the bare wafer 72 but is made of quartz, instead of Si. When the surface area S per unit region of the bare wafer 76 is obtained in the same manner as the first embodiment, the relationship with the surface area S0 per unit region of the wafer 10 becomes S/S0<1.0.

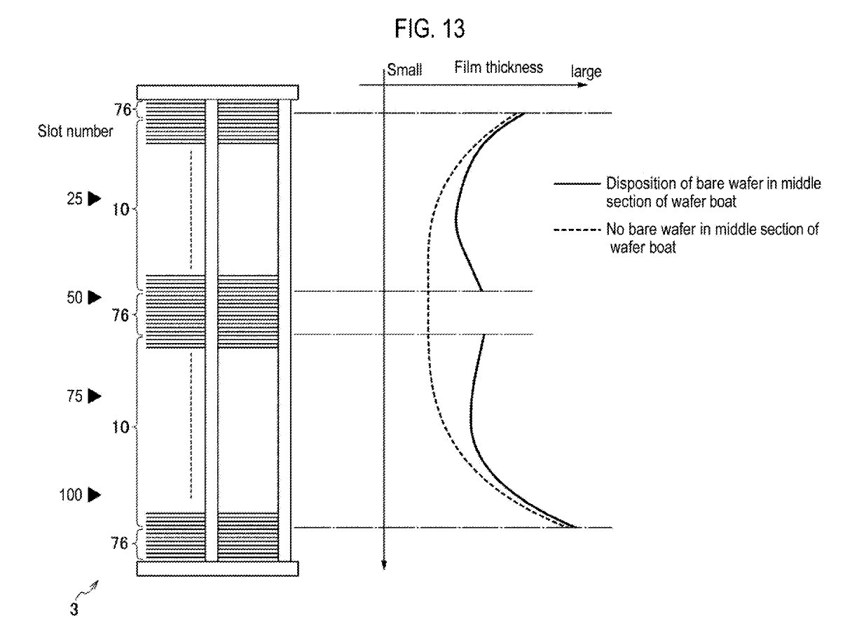

As shown in FIG. 13, slots in which the wafers 10 and 76 are mounted are different from those of the second and third embodiments. The bare wafers 76 are mounted in a plurality of slots at an upper section and in a plurality of slots at a lower section of the wafer boat 3 as in the second and third embodiments. In addition, the bare wafers 76 are mounted in slots of which numbers are consecutive in the middle section of the wafer boat 3. In the example of FIG. 13, the bare wafers 76 are consecutively mounted in slots around Slot Nos. 50 to 60. The wafers 10 are mounted in slots in which the bare wafers 76 are not mounted.

Also in the fourth embodiment, the filming forming treatment and the cleaning treatment are performed in the same manner as the other embodiments. Since the plurality of bare wafers 76 are mounted in the middle section of the wafer boat 3, the consumption amount of the gas is reduced in the vicinity of the middle section during the film forming treatment. Therefore, the supply amount of a gas is increased for the wafers 10 mounted in slots close to the slots with the bare wafers 76 mounted.

In FIG. 13, a curve indicated by a dotted line shows a film thickness distribution of the wafers 10 when the film forming treatment is performed with the bare wafers 76 mounted only at the upper and lower sections of the wafer boat 3. A curve indicated by a solid line shows a film thickness distribution of the wafers 10 when the film forming treatment is performed with the bare wafers 76 mounted also in the middle section of the wafer boat 3 as described above. As shown in the respective graphs, when the bare wafers 76 are mounted in the middle section, the consumption amount of a gas in the middle section is suppressed as described above. Hence, from the upper and lower sections of the wafer boat 3 toward the middle section, the film thickness decreases once and then increases. Such a film thickness distribution suppresses a variation in film thickness as compared to the case without the bare wafers 76 mounted in the middle section.

Since the bare wafers 76 are made of quartz as described above, they are loaded along with the wafer boat 3 into the reaction tube 11 during the cleaning treatment, as in the first embodiment. In the same manner as the quartz wafers 71 of the first embodiment, the bare wafers 76 may be fixed or detachably attached to the wafer boat 3. Although the plurality of bare wafers 76, which are plate-shaped members between the target substrates, are mounted in the middle section of the wafer boat 3 in order to sufficiently improve the supply distribution of a gas, only one bare wafer 76 may be mounted.

The fourth embodiment may be combined with the other embodiments. Specifically, the bare wafers 76 are used as the wafers mounted respectively in the plurality of slots at the upper and lower sections of the wafer boat 3 in FIG. 13. However, when combined with the first embodiment, the film forming treatment is performed with, for example, the quartz wafers 71 mounted instead of the bare wafers 76. Moreover, the film forming treatment may be performed while the wafer boat 3 mounted with the respective wafers 10 and 76 as shown in FIG. 13 is loaded into the reaction tube 11 with a roughened inner surface as described in the second embodiment. Further, the film forming treatment may be performed while the respective wafers 10 and 76 are mounted as shown in FIG. 13 in the wafer boat 3 with the ceiling plate 31 and bottom plate 32 roughened as described in the third embodiment. That is, the film forming treatment may be performed in a state that one bare wafer or a plurality of bare wafers 76 are disposed between the wafers 10 as described above and members made of quartz and having relatively large surface areas are disposed above and below the wafers 10 in order to adjust a gas distribution.

Although the vertical heat treatment apparatus 1 is configured to perform ALD, the present disclosure may be applied to a batch type treatment apparatus for forming a film by supplying a gas. Thus, the present disclosure may be applied to a vertical heat treatment apparatus for performing CVD. Further, the respective embodiments described above may be implemented in combination with one another. For example, in the first embodiment, the film forming treatment may be performed using the reaction tube 11 formed with the roughness as described in the second embodiment. In the first to third embodiments, the bare wafers 76 may be disposed between a group of wafers 10 and a group of wafers 10 by applying the fourth embodiment. Further, in the second and third embodiments, the film forming treatment may be performed by mounting the bare wafers 76 instead of the bare wafers 72.

Meanwhile, it may be considered that wafers 10 per every lot carried into the vertical heat treatment apparatus 1 have different surface areas. That is, it may be considered that the wafers are subjected to different treatments for every lot and they are mounted in the wafer boat 3 in a state that line width of patterns or thickness of a film formed with convex and concave portions is different. In this case, for example, plural kinds of quartz wafers 71 in the first embodiment, which are detachably attached to the wafer boat 3 and have different surface areas, are prepared. Among the plural kinds of quartz wafers 71, quartz wafers 71 to be mounted in the wafer boat 3 may be selected according to the lot of wafers 10 on which the film forming treatment is performed in the vertical heat treatment apparatus 1. Accordingly, the amount of a gas supplied to the wafers 10 at the upper and lower sections of the wafer boat 3 can be controlled for every lot of wafers 10, thereby further improving uniformity of film thicknesses of the wafers 10 among respective slots.

### (Evaluation Test)

Evaluation tests performed according to the present disclosure will be described. In Evaluation Test 1, as described in the BACKGROUND, bare wafers 72 were mounted in a plurality of slots at an upper section of the wafer boat 3 and a plurality of slots at a lower section of the wafer boat 3, wafers 10 were mounted in other slots, and a film forming treatment was performed in the vertical heat treatment apparatus. After the film forming treatment, the film thickness of the wafer 10 in each slot was measured. Further, in Evaluation Test 2, test wafers were mounted instead of the bare wafers 72 and a film forming treatment was performed. The test wafer has the same surface area as the wafer 10 and is made of the same material as the wafer 10. The surface area of both the wafer 10 and the test wafer is three times greater than that of the bare wafer 72.

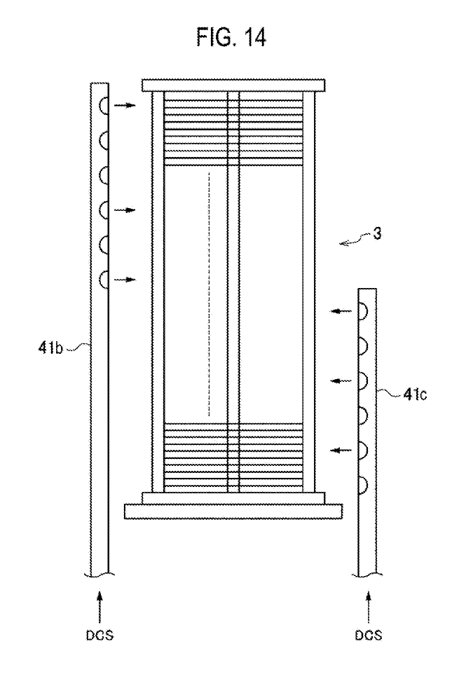

Although an apparatus configured to be approximately similar to the apparatus of the aforementioned embodiment was used as the vertical heat treatment apparatus used in this evaluation test, an injector for supplying DCS gas is configured as shown in FIG. 14. That is, the injector was configured such that a raw material gas supply nozzle 41b for supplying a gas to the upper section of the wafer boat 3 and a first raw material gas supply nozzle 41c for supplying a gas to the lower section of the wafer boat 3 were installed and DCS gas was supplied from each of the nozzles 41b and 41c.

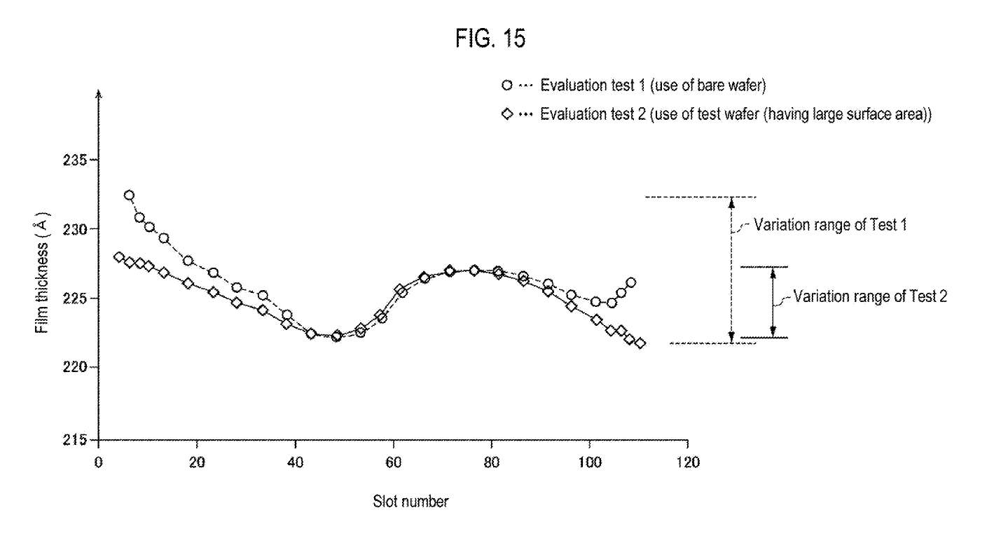

The graph of FIG. 15 is a graph showing results of Evaluation Tests 1 and 2. The slot numbers are represented on the abscissa axis, and the measured film thicknesses (unit: A) of the wafers 10 are represented on the ordinate axis. Further, in each of the evaluation tests, a variation range of film thicknesses among the slots mounted with the wafers 10 is indicated by an arrow. As clearly seen from FIG. 15, in Evaluation Test 1, the film thicknesses of the wafers 10 in the slots close to slots at the upper and lower sections, i.e., in the slots close to slots mounted with the bare wafers 72, are larger than those in Evaluation Test 2. For this reason, in Evaluation Test 1, a variation in film thicknesses of the wafers 10 among the slots is larger than that in Evaluation Test 2. On the contrary, in Evaluation Test 2, film thicknesses of the wafers 10 in the slots at the upper and lower sections are prevented from increasing, thereby suppressing the variation in film thickness among the slots. From the results of these tests, as described in each of the embodiments, it can be found that it is effective to install members having large surface areas above and below a region in which the group of wafers 10 is disposed.

According to the present disclosure, gas distribution adjusting members made of quartz are provided to be positioned respectively above and below a region in which a plurality of target substrates, which are held and supported by a substrate holding and supporting unit, are disposed. Thus, gas supply amounts into above and below the substrate holding and supporting unit can be adjusted respectively, thereby improving uniformity of film thicknesses among the substrates. Further, since the gas distribution adjusting members are made of quartz, the gas distribution adjusting members are difficult to be etched by a cleaning gas, which is a fluorine-based gas including fluorine or a fluorine compound supplied into the reaction tube, as compared with the gas distribution adjusting members made of silicon. Thus, the gas distribution adjusting members can be cleaned together with the interior of the reaction tube by the gas, thereby saving labor for operating an apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A vertical heat treatment apparatus for performing a film forming treatment on a plurality of target substrates by heating the target substrates with a heating unit in a state that the target substrates are held and supported by a substrate holding and supporting unit in a vertical reaction chamber, each of the target substrates having a surface with convex and concave portions, the apparatus comprising:
a gas supply unit that supplies a film forming gas into the reaction chamber; and
a plurality of gas distribution adjusting members made of quartz and installed to be positioned respectively above and below a region in which the plurality of target substrates held and supported by the substrate holding and supporting unit are disposed,
wherein S is a surface area per unit region of the gas distribution adjusting members and S0 is a surface area per unit region obtained by dividing a surface area of the target substrate by a surface area calculated based on an external dimension of the target substrate, and a value (S/S0) obtained by dividing S by S0 is set to be 0.8 or more.

2. The apparatus of claim 1, wherein at least one of the plurality of gas distribution adjusting members installed above the region in which the plurality of target substrates are disposed is a first plate-shaped member installed in the substrate holding and supporting unit.

3. The apparatus of claim 2, wherein the first plate-shaped member is a plate-shaped member to be transferred by a transfer mechanism for transferring the target substrates.

4. The apparatus of claim 2, wherein the first plate-shaped member is fixed to a pillar at a position below a ceiling plate of the substrate holding and supporting unit.

5. The apparatus of claim 2, wherein the first plate-shaped member is a ceiling plate of the substrate holding and supporting unit.

6. The apparatus of claim 1, wherein at least one of the plurality of gas distribution adjusting members installed above the region in which the plurality of target substrates are disposed is a ceiling portion of the reaction chamber.

7. The apparatus of claim 1, wherein at least one of the plurality of gas distribution adjusting members installed below the region in which the plurality of target substrates are disposed is a second plate-shaped member installed in the substrate holding and supporting unit.

8. The apparatus of claim 7, wherein the second plate-shaped member is a plate-shaped member to be transferred by a transfer mechanism for transferring the target substrates.

9. The apparatus of claim 7, wherein the second plate-shaped member is fixed to a pillar at a position above a bottom plate of the substrate holding and supporting unit.

10. The apparatus of claim 7, wherein the second plate-shaped member is a bottom plate of the substrate holding and supporting unit.

11. The apparatus of claim 1, wherein at least one of the plurality of gas distribution adjusting members installed below the region in which the plurality of target substrates are disposed is an inner wall portion of the reaction chamber.

12. The apparatus of claim 1, further comprising at least one plate-shaped member between the target substrates in a region in which the target substrates are inserted, the plate-shaped member between the target substrates being a gas distribution adjusting member held and supported by the substrate holding and supporting unit,
wherein S is a surface area per unit region of the plate-shaped member between the target substrates and S0 is a surface area per unit region obtained by dividing the surface area of the target substrate by the surface area calculated based on the external dimension of the target substrate, and the value (S/S0) obtained by dividing S by S0 is set to a value less than 1.0.

13. The apparatus of claim 12, wherein a plurality of plate-shaped members between the target substrates are consecutively held and supported one above another by the substrate holding and supporting unit.

14. The apparatus of claim 12, wherein the plate-shaped member between the target substrates is made of quartz.

15. The apparatus of claim 12, wherein the plate-shaped member between the target substrates is fixed to the substrate holding and supporting unit.

16. A method of operating a vertical heat treatment apparatus for performing a film forming treatment on a plurality of target substrates by heating the target substrates with a heating unit in a state that the target substrates are held and supported by a substrate holding and supporting unit in a vertical reaction chamber, each of the target substrates having a surface with convex and concave portions, the method comprising:
supplying a film forming gas into the reaction chamber by using a gas supply unit in a state that gas distribution adjusting members made of quartz are positioned respectively above and below a region in which the plurality of target substrates held and supported by the substrate holding and supporting unit are disposed,
wherein S is a surface area per a unit region of the gas distribution adjusting members and S0 is a surface area per unit region obtained by dividing a surface area of the target substrate by a surface area calculated based on an external dimension of the target substrate, and a value (S/S0) obtained by dividing S by S0 is set to be 0.8 or more.

17. The method of claim 16, wherein the gas distribution adjusting member installed above the region in which the plurality of target substrates are disposed is a plate-shaped member installed in the substrate holding and supporting unit.

18. The method of claim 16, wherein the gas distribution adjusting member installed above the region in which the plurality of target substrates are disposed is a ceiling portion of the reaction chamber.

19. The method of claim 16, wherein the gas distribution adjusting member installed below the region in which the plurality of target substrates are disposed is a plate-shaped member installed in the substrate holding and supporting unit.

20. The method of claim 16, wherein the gas distribution adjusting member installed below the region in which the plurality of target substrates are disposed is an inner wall portion of the reaction chamber.

21. The method of claim 16, comprising:
supplying the film forming gas into the reaction chamber by using the gas supply unit in a state that at least one plate-shaped member between the target substrates is held and supported by the substrate holding and supporting unit in a region in which the target substrates are inserted, the plate-shaped member between the target substrates being a gas distribution adjusting member,
wherein if S is a surface area per unit region for the plate-shaped member between the target substrates and S0 is a surface area per unit region obtained by dividing the surface area of the target substrate by the surface area calculated based on the external dimension of the target substrate, the value (S/S0) obtained by dividing S by S0 is set to a value less than 1.0.

22. The method of claim 21, wherein a plurality of plate-shaped members between the target substrates are consecutively held and supported one above another by the substrate holding and supporting unit.

23. The method of claim 21, wherein the plate-shaped member between the target substrates is made of quartz.

24. A non-transitory computer-readable storage medium for storing a program used in a vertical heat treatment apparatus in order to perform the method of claim 16.
